(19) United States
(12) Patent Application Publication
(10) Pub. No.: US 2010/0107389 A1
(43) Pub. Date: May 6, 2010

(54) METHOD OF FABRICATING AN ELECTRODE FOR A BULK ACOUSTIC RESONATOR

(75) Inventors: Winfried Nessler, Munich (DE); Robert Thalhammer, Munich (DE); Thomas Rainer Herzog, Hoehenkirchen-Siegertsbrunn (DE); Martin Handtmann, Munich (DE); Lueder Elbrecht, Munich (DE)

Correspondence Address: Kathy Manke;Avago Technologies Limited, 4380 Ziegler Road, Fort Collins, CO, 80525, US

(73) Assignee: Avago Technologies Wireless IP (Singapore) Pte. Ltd., Singapore (SG)

(21) Appl. No.: 12/646,084

(22) Filed: Dec. 23, 2009

Related U.S. Application Data
(63) Continuation-in-part of application No. 10/888,429, filed on Jul. 9, 2004, now Pat. No. 7,657,983.

(30) Foreign Application Priority Data
Jan. 11, 2002 (DE) 102 00 741.1-33
Dec. 12, 2002 (EP) PCT/EP02/14190

(51) Int. Cl. H04R 31/00; H01L 41/083; H01L 41/22

(52) U.S. Cl. 29/25.35; 29/594; 29/847

(57) ABSTRACT

In one embodiment, a method of producing a resonator in thin-film technology is described. The resonator comprises a piezoelectric layer arranged at least partially between a lower electrode and an upper electrode, the resonator being formed over a substrate. The method comprises: forming the lower electrode of the resonator over the substrate; depositing and patterning an insulating layer over the substrate, the insulating layer comprising a thickness substantially equal to a thickness of the lower electrode; removing a portion of the insulating layer to partially expose a surface of the lower electrode; removing a portion of the insulating layer over the surface of the lower electrode by chemical mechanical polishing; forming the piezoelectric layer over the lower electrode; and producing the upper electrode on the piezoelectric layer.

### CROSS-REFERENCE TO RELATED APPLICATIONS

The present application is a continuation-in-part application under 37 C.F.R. §1.53(b) of commonly owned U.S. patent application Ser. No. 10/888,429 entitled “Method of Producing a Topology-Optimized Electrode for a Resonator in Thin-Film Technology” filed on Jul. 9, 2004 naming Robert Aigner, et al. as inventors (referred to herein as the ‘parent application’). Priority to the parent application is claimed under 35 U.S.C. §120 and the entire disclosure of the parent application is specifically incorporated herein by reference.

### BACKGROUND

In many electronic applications, electrical resonators are used. For example, in many wireless communications devices, radio frequency (RF) and microwave frequency resonators are used as filters to improve reception and transmission of signals. Filters typically include inductors and capacitors, and more recently resonators.

As will be appreciated, it is desirable to reduce the size of components of electronic devices. Many known filter technologies present a barrier to overall system miniaturization. With the need to reduce component size, a class of resonators based on the piezoelectric effect has emerged. In piezoelectric-based resonators, acoustic resonant modes are generated in the piezoelectric material. These acoustic waves are converted into electrical waves for use in electrical applications.

One type of piezoelectric resonator is a Bulk Acoustic Wave (BAW) resonator. The BAW resonator includes an acoustic stack comprising, inter alia, a layer of piezoelectric material disposed between two electrodes. Acoustic waves achieve resonance across the acoustic stack, with the resonant frequency of the waves being determined by the materials in the acoustic stack. One type of BAW resonator comprises a piezoelectric film for the piezoelectric material. These resonators are often referred to as Film Bulk Acoustic Resonators (FBAR).

In the production of frequency filters in thin-film technology FBARs, the piezoelectric layer, e.g. an AlN layer, a ZnO layer, or PZT layer, is typically deposited by means of a reactive sputtering process. The reactive sputtering process is preferred because it requires a relatively low process temperature and offers deposition conditions which are easy to control and reproduce. In addition, the reactive sputtering process leads to a high-quality thin layer.

One problem associated with producing the thin layers arises due to the specific growth conditions of piezoelectric layers, in which crystallites having a certain preferred orientation grow faster than those with other orientations. In combination with the poor edge coverage of a sputtering process, these specific growth conditions of the piezoelectric layers lead to the formation of growth defects at the topology steps. Piezoelectric layers having such growth defects can impact the performance of the FBAR. For example, and among other considerations in fabricating FBARs are a substantially precise resonance frequency and an optimize quality factor (Q) value. Among other considerations optimization of Q of a resonator are an optimization of the effective piezoelectric coupling factor (kₜ²), and suppression of spurious (lateral) modes. Growth defects and non-uniformities in the piezoelectric layer can adversely impact the precision of the resonance frequency and the Q factor, among other characteristics of the FBAR.

Certain growth defects are explained below in more detail with reference to FIG. 1. FIG. 1A shows an arrangement which includes a substrate 100 comprising a first, lower surface 102 as well as a second, upper surface 104. A first, lower electrode 106 is formed in a portion on the upper surface 104, which electrode 106 in turn includes a first, lower surface 108 as well as a second, upper surface 110. By means of the above-mentioned sputtering process, a piezoelectric layer 112, which is an AlN layer in the example depicted, has been produced on that portion of the upper surface 104 of substrate 100 which is not covered by the electrode 106 as well as on the upper surface 110 of electrode 106.

As may be seen from FIG. 1A, due to the arrangement of electrode 106 on surface 104 of substrate 100, a step 114 (topology step) is formed where a growth defect occurs during a sputtering process due to the poor edge coverage of the sputtering process and due to the specific growth conditions of the piezoelectric layer 112. This growth defect is indicated generally by reference numeral 116 in FIG. 1A. By reference numeral 118, FIG. 1A depicts a preferred direction of growth of the piezoelectric layer in the various areas. In the area of step 114, these lines 118 may be seen to be offset, which has led to the occurrence of the growth defect 116. The lines of offset and the defects resulting therefrom are undesirable for the reasons stated below and lead to problems regarding the reliability of the device to be produced, in particular in connection with the subsequent deposition of an upper electrode.

Specifically, in a subsequent deposition and structuring of metallization for producing the upper electrode, a metallic spacer will remain which may subsequently lead to electrical short-circuits, whereby the functionality of the device, e.g. a filter, may be degraded or completely destroyed. FIG. 1B represents the structure which results, starting from FIG. 1A, once a metallization which has been subjected to full-area deposition, has been structured for producing an upper electrode. FIG. 1B shows a second, upper electrode 120 formed on a surface 122 of the piezoelectric layer 112 which is facing away from substrate 100, such that this upper electrode 120 is at least partly opposite the electrode 106. The thin-layer bulk acoustic resonator is formed in that area in which electrode 106 and upper electrode 120 overlap. As may also be seen in FIG. 1B, a rest of metal 124 (metal spacer) has remained in the area of the growth defect 116. This metal spacer 124 leads to the above-mentioned problems in connection with electric short-circuits and the like.

The quality of the piezoelectric layer is also affected by how the bottom electrode is patterned. Notably, the bottom electrode forms the substrate over which the piezoelectric layer is deposited, and, in turn, impacts the quality of the piezoelectric layer formed thereover. Generally, it is desirable to have a planar surface over which to form the piezoelectric layer, or a surface comprising an atomic structure (e.g., a seed layer over the bottom electrode) conducive to growth in a desired crystal orientation (e.g., orientation depicted by reference character 118). Providing such surfaces improves the quality of the piezoelectric layer by avoiding a random orientation of the crystal axes of the grains in the piezoelectric layer. This is also true, if the piezoelectric layer is not directly deposited onto the bottom electrode, but a thin seed layer is grown first.

Furthermore, in addition to the quality of the piezoelectric layer, the effective coupling of the resonator may be reduced by additional dielectric layers between the electrodes, for example native oxides, seed layers. These additional dielectric layers may be a result of the process used to form the bottom electrode.

As is known, the resonance frequency of an FBAR is impacted generally by the layers comprising the resonator (sometimes referred to as the acoustic stack), and specifically by the homogeneity of the thickness of the layers. As should be appreciated, a planar topology is beneficial to this end. Otherwise, the resonance frequencies across the resonator area would be slightly different. The resulting inferences and phase shifts reduces the Q value of the resonator and supports deleterious spurious modes.

Known methods aimed at providing a substantially planar topology acoustic stack by providing a substantially planar bottom electrode have certain shortcomings. Among other shortcomings, known methods can result in a concave profile particularly in the center of the acoustic stack (so-called dishing effect). Ultimately, this known method can result in non-uniformity of the thickness of the layers in the acoustic stack, which has a deleterious impact on the Q factor of the resulting FBAR. Furthermore, other known methods aimed at providing a substantially planar topology can result in the surface of the bottom electrode's being exposed during many subsequent process steps after its deposition. In particular, these processes allow contaminants (e.g., oxides) to form over the surface. Such contaminants can result in growth defects in the piezoelectric layer formed over the bottom electrode. Again, growth defects in the piezoelectric layer can have an adverse impact on the performance of the resultant FBAR.

What is needed, therefore, is a method of fabricating a BAW resonator that overcomes at least the drawbacks described above.

### SUMMARY

In accordance with a representative embodiment, a method of producing a resonator in thin-film technology is described. The resonator comprises a piezoelectric layer arranged at least partially between a lower electrode and an upper electrode, the resonator being formed over a substrate. The method comprises: forming the lower electrode of the resonator over the substrate; depositing and patterning an insulating layer over the substrate, the insulating layer comprising a thickness substantially equal to a thickness of the lower electrode; removing a portion of the insulating layer to partially expose a surface of the lower electrode; removing a portion of the insulating layer over the surface of the lower electrode by chemical mechanical polishing; forming the piezoelectric layer over the lower electrode; and producing the upper electrode on the piezoelectric layer.

In accordance with another representative embodiment, a method of producing a resonator in thin-film technology is disclosed. The resonator comprises a piezoelectric layer arranged at least partially between a lower electrode and an upper electrode, the resonator being formed over a substrate. The method comprises forming the lower electrode of the resonator over the substrate; forming a protection layer over the lower electrode; depositing an insulating layer over the substrate and partially over the protection layer, the insulating layer comprising a thickness substantially equal to a combined thickness of the lower electrode and the protection layer; removing the insulating layer over the portion of the protection layer; forming the piezoelectric layer over the protection layer; and forming the upper electrode over the piezoelectric layer.

### BRIEF DESCRIPTION OF THE DRAWINGS

The representative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1A and 1B depict a known method of producing a BAW resonator wherein a growth defect results due to a topology step.

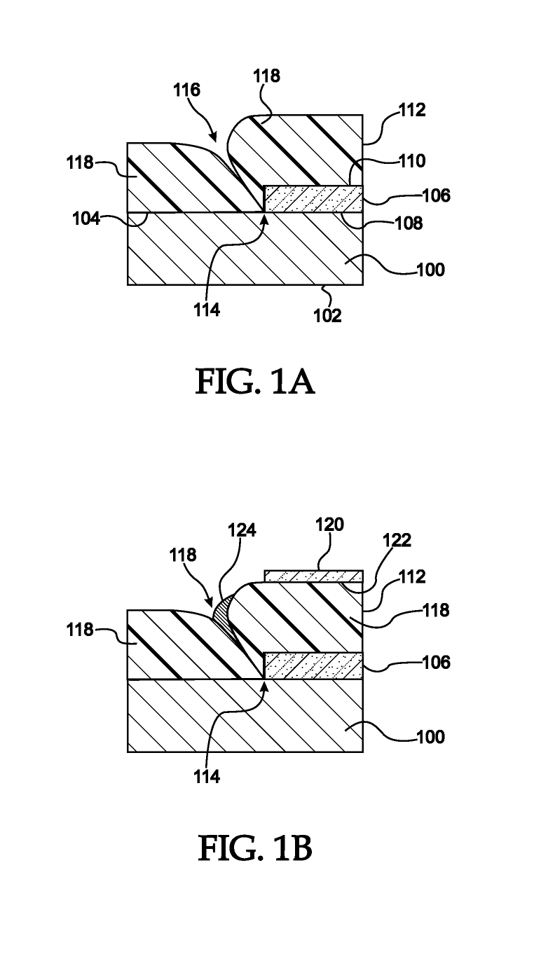

FIGS. 2A to 2C show a cross-sectional view of a method of fabricating a BAW resonator in accordance with a representative embodiment.

FIGS. 3A to 3C show a cross-sectional view of a method of fabricating a BAW resonator in accordance with a representative embodiment.

FIG. 4 shows a cross-sectional view of a BAW resonator in accordance with a representative embodiment.

FIGS. 5A-5B show cross-sectional views of BAW resonators in accordance with a representative embodiment.

FIGS. 6A-6D show a cross-sectional view of a method of fabricating a BAW resonator in accordance with a representative embodiment.

### DEFINED TERMINOLOGY

It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

### DETAILED DESCRIPTION

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the illustrative embodiments. Such methods and apparati are clearly within the scope of the present teachings.

Generally, it is understood that the drawings and the various elements depicted therein are not drawn to scale. Further, relative terms, such as “above,” “below,” “top,” “bottom,” “upper” and “lower” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element.

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparati and methods may be omitted so as to not obscure the description of the illustrative embodiments. Such methods and apparatuses are clearly within the scope of the present teachings.

Certain aspects of the present teachings are relevant to components of FBAR devices, FBAR-based filters, their materials and methods of fabrication. Many details of FBARs, materials thereof and their methods of fabrication may be found in one or more of the following U.S. patents and patent applications: U.S. Pat. No. 6,107,721, to Lakin; U.S. Pat. Nos. 5,587,620, 5,873,153 and 6,507,983 to Ruby, et al.; U.S. patent application Ser. No. 11/443,954, entitled “Piezoelectric Resonator Structures and Electrical Filters” to Richard C. Ruby, et al.; U.S. patent application Ser. No. 10/990,201, entitled “Thin Film Bulk Acoustic Resonator with Mass Loaded Perimeter” to Hongjun Feng, et al.; and U.S. patent application Ser. No. 11/713,726, entitled “Piezoelectric Resonator Structures and Electrical Filters having Frame Elements” to Jamneala, et al.; and U.S. patent application Ser. No. 11/159,753, entitled “Acoustic Resonator Performance Enhancement Using Alternating Frame Structure” to Richard C. Ruby, et al. The disclosures of these patents and patent applications are specifically incorporated herein by reference. It is emphasized that the components, materials and method of fabrication described in these patents and patent applications are representative and other methods of fabrication and materials within the purview of one of ordinary skill in the art are contemplated.

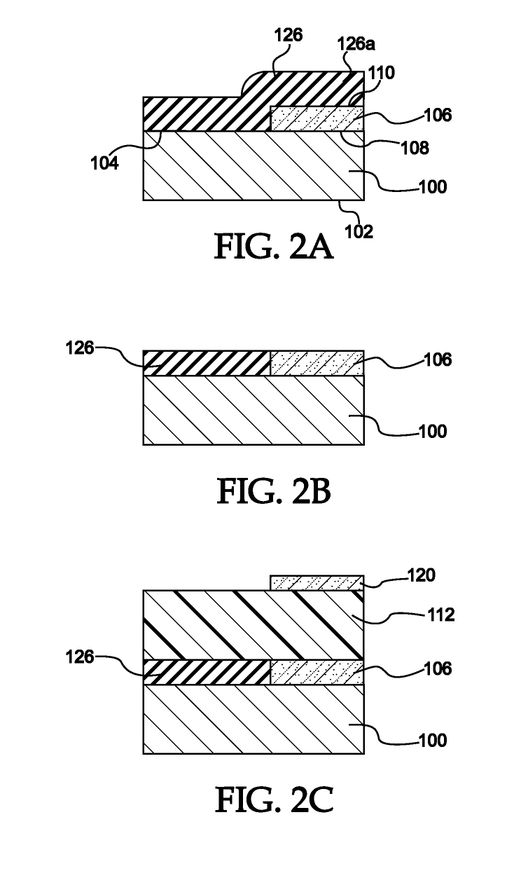

FIG. 2A shows substrate 100, an electrode 106, preferably made of aluminum, being formed on a portion of the upper surface 104 of substrate 100. Alternatively, electrode 106 may also be formed of tungsten, a combination of aluminum and tungsten, or other suitable metals.

To avoid the topology step, an insulating layer 126 is deposited, in accordance with the embodiment described with regard to FIG. 2, onto the exposed portion of the substrate surface 104 as well as onto the upper surface 110 of electrode 106. In the embodiment depicted, the insulating layer 126 is a layer of silicon oxide or a layer of silicon nitride.

The structure depicted in FIG. 2A is subsequently subjected to a chemical-mechanical thinning process, by means of which a portion 126a, arranged in the area of electrode 106, is thinned such that the upper surface 110 of electrode 106 is exposed. In addition, the remaining portions of the insulating layer 126 are thinned such that the thickness of the electrode 106 and the thickness of the insulating layer 126 are substantially identical, so that a substantially planar surface results, as is shown in FIG. 2B.

FIG. 2C depicts the structure resulting from the polishing step, and, as may be seen, those surfaces of the insulating layer 126 and of the electrode 106 which are facing away from the substrate are substantially planar, and this surface has the piezoelectric layer 114 deposited thereon, which, in turn, has the upper electrode 120 deposited thereon.

The advantage of the inventive method is evident, since the problems due to growth defects which have been described and are known in the prior art are avoided simply by eliminating a topology step in the production of the resonator. This has the advantage that the electrical short-circuits mentioned, which may degrade or even destroy the function of the device (e.g. a filter including corresponding resonators) will not occur, that a desired ESD resistance is achieved due to the substantially fully planar arrangement, and that the suppression of undesired spurious modes is improved, since a defined geometry (thickness) exists in the area outside of the upper electrode 120 across a wide area.

The above-described removal of the dielectric layer 126A above the electrode 106 is effected, in the embodiment depicted in FIG. 2, directly with a very hard polishing pad. In this case it is necessary to have a high polishing selectivity between the dielectric layer 126 and the material of the electrode 106 to ensure that when reaching the upper surface 110 of the electrode 106, substantially no electrode material will be lifted off.

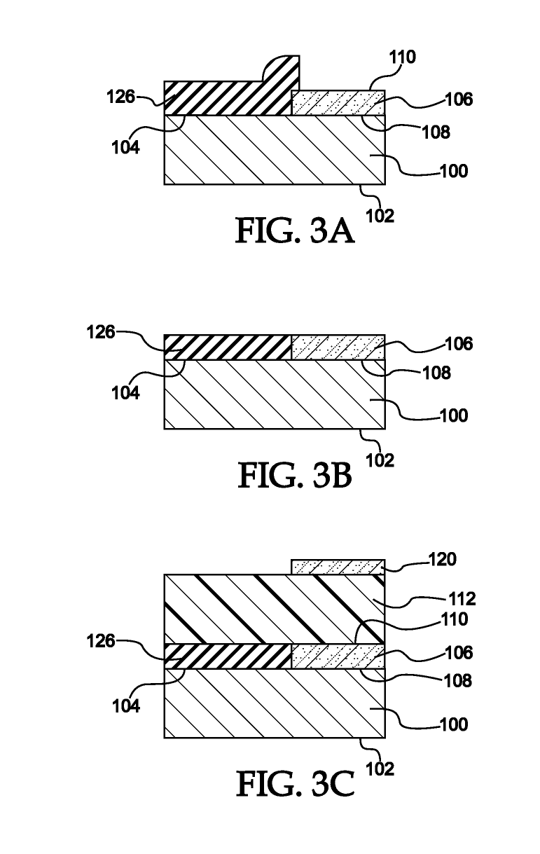

In order to avoid potential problems in the required high polishing selectivity between the dielectric layer 126 and the material of the electrode 106, another approach is pursued, in accordance with a second embodiment of the present invention, which imposes clearly fewer requirements with regard to the hardness of the pad and/or the selectivity of the polishing process. This further embodiment will be explained below in more detail with reference to FIG. 3, identical or similar elements also being given the same reference numerals.

The embodiment depicted in FIG. 3 is based on a structure as is represented in FIG. 2A, i.e. a structure wherein the electrode 106 has already been deposited on substrate 100, and the insulating layer 126 has already been deposited on the electrode 106. Unlike the embodiment described in FIG. 2, chemical-mechanical polishing of the entire surface is not performed here, but, instead, the dielectric layer 126 is removed in the area within the electrode 106, e.g. by etching the insulating layer 126, using a photolithographic mask (not depicted), so as to expose the upper surface 110 of electrode 106 at least partially, as is shown in FIG. 3A. In one embodiment, a so-called ‘lift-off’ method may be used to pattern the insulating layer 126 to provide the resulting structure depicted in FIG. 3A. The method comprises spinning on a layer of sacrificial layer (e.g. photoresist, not shown) over the substrate 100[?]. The sacrificial layer is then patterned by a known patterning method to produce a pattern on the substrate 100. For example, if the sacrificial layer comprises a photoresist, the patterning comprises exposing and developing a photoresist. After the patterning of the sacrificial layer is completed, the insulating layer 126 is deposited over the substrate 100. The sacrificial layer is then dissolved and thereby removed from those portions of the insulating layer 126 that were disposed on top of the sacrificial layer. This then leaves the insulating layer 126 only in areas that have not been covered by sacrificial layer previously.

As may be seen, a narrow ridge 126A of the portion of the insulating layer 126 above the electrode 106 remains. The advantage of this approach is that now only the narrow ridge 126A remains, which, contrary to the distance or polishing of the entire insulating layer 126, may be removed within a very short time and under clearly relaxed polishing conditions, so that the structure shown in FIG. 3B results.

FIG. 3C depicts the structure resulting after the polishing and the growing of the piezoelectric layer 114 as well as of the upper electrode 120, and the structure shown in FIG. 3C corresponds to the structure depicted in FIG. 2C. The advantage of the approach described in FIG. 3 is that, with this embodiment, which uses the additional mask and the etching of the insulating layer 126, the undesired topology step may be prevented in a manner which is particularly simple from a technical point of view.

Another embodiment not shown in the figures consists in that on the surface of the substrate 100, the insulating layer 126 is initially deposited, wherein an opening, preferably down to the substrate surface 104, is opened in a subsequent step, in which opening the metal of the bottom electrode 106 is then deposited, such that the surfaces of the dielectric layer 126 and of the bottom electrode 106 created are substantially flush.

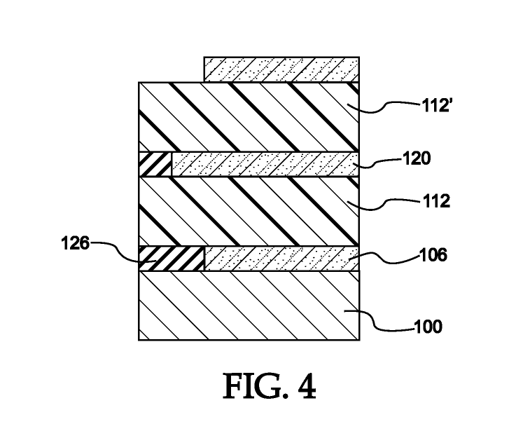

The above-described method of producing an electrode without a topology step may also be used for so-called stacked BAW resonators/filters having a plurality of piezoelectric layers. FIG. 4 depicts such a resonator. SBARs comprise stacking two or more layers of piezoelectric material with electrodes between the piezoelectric layers and on the top and bottom of the stack. Such SBARs are described, for example in commonly owned U.S. Pat. Nos. 5,587,620 and 6,060,818, to Ruby, et al. Furthermore, the piezoelectric layers 112, 112′ may comprise antiparallel C-axes (e.g., C_{N} polarity and Cp polarity) or both comprising C_{N} polarity may be useful in CRF applications. Further details of providing parallel and antiparallel C-axes are described, for example, in commonly-owned U.S. patent application Ser. No. 12/201,641 entitled “Single Cavity Acoustic Resonators and Electrical Filters Comprising Single Cavity Acoustic Resonators” filed on Aug. 29, 2008 to Bradley, et al.; and in commonly owned U.S. Pat. No. 7,515,018 to Handtmann, et al. The disclosures of U.S. Pat. Nos. 5,587,620; 6,060,818; 6,987,433; 7,091,649; and 7,515,018 and the disclosure of U.S. patent application Ser. No. 12/201,641 are specifically incorporated herein by reference. It is emphasized that the noted applications are intended merely to illustrate applications of the methods of the present teachings, and that the application of the methods of fabricating piezoelectric materials of the present teachings are not limited to these illustrative applications.

As may be seen, the method of producing the electrode of a representative embodiment described above was both applied to the bottom electrode 106, intermediate electrode 120. Thus, both piezoelectric layers 112, 112′ may be deposited without lines of offset. Embodiments having more than two piezoelectric layers may be produced by analogy therewith.

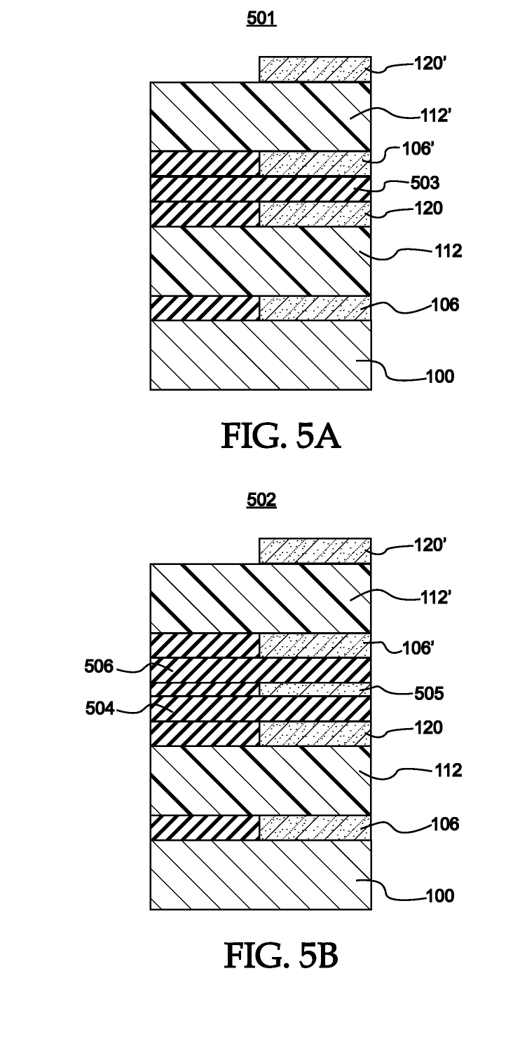

FIGS. 5A-5B show cross-sectional views of BAW resonators in accordance with a representative embodiment. In FIG. 5A, a BAW resonator 501 comprises substrate 100 and lower electrode 106, piezoelectric layer 112 and upper electrode 120. A second lower electrode 106′ is provided over an acoustic decoupling layer 503. A second piezoelectric layer 112′ is provided over the second lower electrode 106′, and a second upper electrode 120′ is provided over the second piezoelectric layer 112′. The BAW resonator 501 thus comprises two piezoelectric layers 112, 112′ formed over respective lower electrodes 106, 106′. The piezoelectric layers 112, 112′ are fabricated by planarizing the respective surfaces of the lower electrodes 106, 106′ using methods described in connection with representative embodiments in FIGS. 2A-4 above. The details of these methods are not presently repeated to avoid obscuring the description of the presently described embodiment.

In a representative embodiment, the BAW resonator 501 comprises a coupled resonator filter (CRF), such as described in commonly owned U.S. Patent Application Publications 20090265903 and 20080055020 to Handtmann, et al.; and U.S. Patent Application Publication 20080297279 to Thalhammer, et al. The disclosures of these publications are specifically incorporated herein by reference. In another representative embodiment, the BAW resonator 501 comprises a film acoustic transformer (FACT). These are merely representative embodiments, and other types of resonators within the purview of one of ordinary skill in the art are contemplated. The acoustic decoupling layer 503 may be as described, for example, in commonly owned U.S. Pat. Nos. 6,720,844 to Lakin; 7,242,270 to Larson III, et al.; 7,561,009 to Larson III, et al.; 7,562,429 to Larson III, et al.; and 7,436,269 to Wang, et al. The disclosures of these patents are specifically incorporated herein by reference. It is emphasized that the acoustic decoupling layer 503 may be of different materials and formed by different methods than those described in the patents to Larson III, et al., and Wang, et al. Such materials and methods of forming such acoustic decoupling layers known to those of ordinary skill in the art are contemplated.

In FIG. 5B, a BAW resonator 503 comprises substrate 100 and lower electrode 106, piezoelectric layer 112 and upper electrode 120. An acoustic isolator structure comprising a first low acoustic impedance layer 504, a high acoustic impedance layer 505, and a second low acoustic impedance layer 506 is provided over the second electrode 120. The acoustic isolator structure, which is often referred to as an acoustic mirror, may be as described in commonly owned U.S. Patent Application Publications: 20070266548 to Fattinger; 20070254397 to Fattinger, et al.; and 20080055020 to Handtmann, et al. The disclosures of these publications are specifically incorporated herein by reference.

A second lower electrode 106′ is provided over the second low acoustic impedance layer 506. A second piezoelectric layer 112′ is provided over the second lower electrode 106′, and a second upper electrode 120′ is provided over the second piezoelectric layer 112′. The BAW resonator 503 thus comprises two piezoelectric layers 112, 112′ formed over respective lower electrodes 106, 106′. The piezoelectric layers 112, 112′ are fabricated by planarizing the respective surfaces of the lower electrodes 106, 106′ methods described in connection with representative embodiments in FIGS. 2A-4 above. The details of these methods are not presently repeated to avoid obscuring the description of the presently described embodiment.

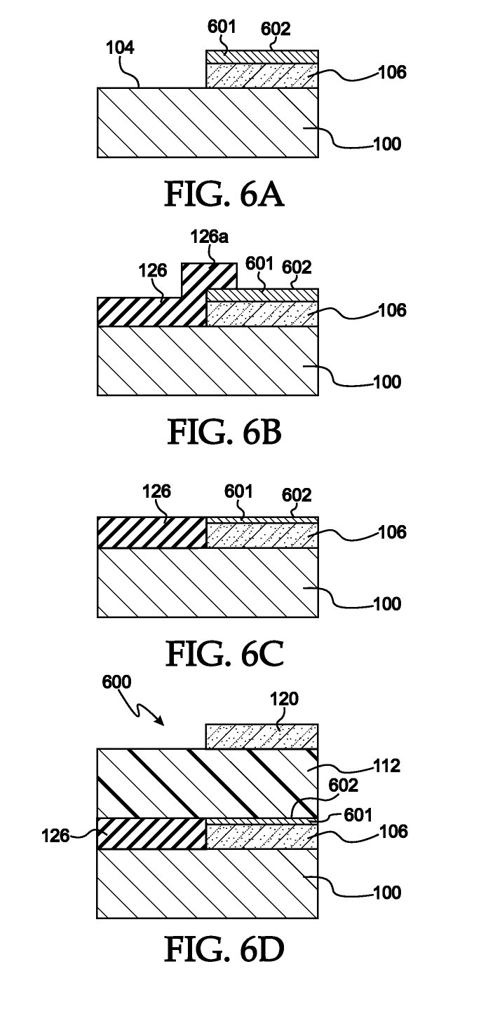

FIGS. 6A-6D show in cross-sectional views, a method of fabricating a BAW resonator in accordance with a representative embodiment. Certain structures, materials, and methods of the representative method of FIGS. 6A-6D are common to those described previously in connection with representative embodiments of FIGS. 2A-5B. The details of these methods are not presently repeated to avoid obscuring the description of the presently described embodiment.

As will become clearer as the present description continues, in accordance with the method of the representative embodiments described in connection with FIGS. 6A-6D provide as a protection layer, one of the layers that is desirably a layer of desired layer stack (acoustic stack) of the resonator, and therefore does not have to be removed. In certain embodiments, the protection layer is a seed layer useful in forming the piezoelectric layer of the acoustic stack. In one aspect, the material selected for the protective layer comprises properties of a comparatively high acoustic sound velocity, low acoustic impedance and is comparatively hard material to withstand the planarizing such as by chemical-mechanical polishing. These properties will substantially reduce the polishing induced non-uniformities that can adversely impact the acoustic performance of the BAW resonator much less than polishing the actual electrode. Ultimately, the acoustic performance is improved because of the robustness of the protection layer and the resulting in fewer non-uniformities created, or because of the lower acoustic impedance or higher acoustic sound velocity the impact of a given mechanical non-uniformity on the acoustic performance will be weaker, or both. Notably, the acoustic sound velocity of the protection layer should be higher or the acoustic impedance of the protection layer should be lower than the respective parameter of the top most layer of the electrode. In representative embodiments, the electrodes may be made of materials of very high acoustic impedance such as tungsten or molybdenum. As an additional benefit of the method described in connection with representative embodiments of FIGS. 6A-6D, the oxidation of the electrode surface can be avoided, particularly if the protection layer is deposited in the same chamber as the top most electrode layer.

FIG. 6A shows substrate 100, lower electrode 106, being formed on a portion of the upper surface 104 of substrate 100. The electrode 106 comprises one or more of tungsten or molybdenum or other suitable metals. Notably, the electrode 106 comprises comparatively high acoustic impedance. A seed layer 601 is provided over the lower electrode 106.

In a representative embodiment, the seed layer 601 is selected to provide protection of the electrode 106 during subsequent processing, and as a seed layer 601 for the deposition of a piezoelectric layer of the desired resonator structure. In one embodiment, the seed layer 601 comprises an amourphous silicon layer. In other embodiments, the seed layer 601 comprises a comparatively thin layer of the desired piezoelectric material used for the piezoelectric layer used in the resonator structure. The seed layer 601 as the protection layer for the lower electrode 106. For example, the piezoelectric layer may be one of AlN, ZnO and PZT, and the seed layer may be a thin layer of the selected piezoelectric layer. Illustratively, the seed layer 601 has a thickness of approximately 1.0 nm to approximately 100 nm.

FIG. 6B an insulating layer 126 is deposited onto the exposed portion of the substrate surface 104 and over a portion of the seed layer 601. In a representative embodiment, the insulating layer 126 comprises a layer of silicon oxide or a layer of silicon nitride. A subsequent CMP thinning process is carried out, by means of which a portion 126a of the insulating layer disposed over a portion of the seed layer 601 is thinned such that an upper surface 602 of electrode the seed layer 601 is exposed. Beneficially, in order to foster planarity, the polishing rate of the seed layer does not exceed the polishing rate of the insulating layer 126. In addition, the remaining portions of the insulating layer 126 are thinned such that the combined thickness of the lower electrode 106 and the seed layer 601 is substantially identical as the thickness of the insulating layer 126 disposed over the upper surface 104 of the substrate 100. The resultant structure is substantially planar and is shown in FIG. 6C.

FIG. 6D shows the acoustic stack comprising the piezoelectric layer 112 formed over the seed layer and the upper electrode 120 formed over the piezoelectric layer 112.

As noted above, in representative embodiments the electrode comprises tungsten or molybdenum for the electrode 106 and aluminum nitride (AlN) as the piezoelectric layer. As AlN is a comparatively hard material of higher sound velocity and lower acoustic impedance than the materials selected for electrode 106 electrode materials, polishing the AlN layer is less critical. Particularly, AlN can be deposited in situ onto the lower electrode 601 of tungsten or molybdenum. Beneficially, the selection of AlN as the seed layer 601 fosters the deposition of a comparatively high quality AlN layer for the piezoelectric layer subsequently formed thereover. Also, the forming of the seed layer 601 will substantially prevent oxidation of the electrodes surface, which can deleteriously impact the quality of the piezoelectric resonator formed thereover. Moreover, no additional seed layer is required, and the resultant acoustic stack comprises only the piezoelectric layer between the electrodes.

Furthermore, the method of the representative embodiments of FIGS. 6A-6D are contemplated for fabricating stacked resonator structures such as SBARs, DBARs, SCFs and CRFs, such as those described above in connection with the representative embodiments of FIGS. 4-5B. As should be appreciated by one of ordinary skill in the art upon review of the present disclosure, such stacked resonator structures may be realized by selectively repeating steps of the method, in combination with the forming of other layers (e.g., acoustic decoupling layers) to realize the desired stacked resonator structures.

While this invention has been described in terms of several representative and illustrative embodiments, there are alterations, permutations, and equivalents which fall within the scope of the present teachings. It should also be noted that there are many alternative ways of implementing the methods and compositions of the present teachings. It is therefore intended that the following appended claims be interpreted as including all such alterations, permutations, and equivalents as fall within the true spirit and scope of the present teachings.

1. A method of producing a resonator in thin-film technology, the resonator comprising a piezoelectric layer arranged at least partially between a lower electrode and an upper electrode, the resonator being formed over a substrate, the method comprising:
forming the lower electrode of the resonator over the substrate;
depositing and patterning an insulating layer over the substrate, the insulating layer comprising a thickness substantially equal to a thickness of the lower electrode;
removing a portion of the insulating layer to partially expose a surface of the lower electrode;
removing a portion of the insulating layer over the surface of the lower electrode by chemical mechanical polishing;
forming the piezoelectric layer over the lower electrode; and
producing the upper electrode on the piezoelectric layer.

2. The method as claimed in claim 1, wherein a portion of the insulating layer not disposed over the lower electrode remains substantially unchanged.

3. The method as claimed in claim 1, removing of the portion of the insulating layer comprises:
etching a part of the insulating layer above the lower electrode using a mask, such that a portion of the upper surface of the lower electrode is exposed; and removing remaining portions of the insulating layer that are located above a plane defined by the surface of the lower electrode.

4. The method as claimed in claim 1, wherein the insulating layer comprises a dielectric material.

5. The method as claimed in claim 4, wherein the dielectric material is selected from the group consisting of a silicon nitride and a silicon oxide.

6. The method as claimed in claim 1, wherein the piezoelectric layer comprises one of AlN, ZnO and PZT.

7. The method as claimed in claim 1, wherein the lower electrode comprises one of aluminum, tungsten, molybdenum, platinum, ruthenium, iridium, or combinations of thereof.

8. The method as claimed in claim 1, wherein the resonator is a BAW resonator.

9. A method of producing a resonator in thin-film technology, the resonator comprising a piezoelectric layer arranged at least partially between a lower electrode and an upper electrode, the resonator being formed over a substrate, the method comprising:
forming the lower electrode of the resonator over the substrate;
forming a protection layer over the lower electrode;
depositing an insulating layer over the substrate and partially over the protection layer, the insulating layer comprising a thickness substantially equal to a combined thickness of the lower electrode and the protection layer;
removing the insulating layer over the portion of the protection layer;
forming the piezoelectric layer over the protection layer; and
forming the upper electrode over the piezoelectric layer.

10. A method as claimed in claim 9, wherein the removing the insulating layer comprises chemically-mechanically polishing.

11. A method as claimed in claim 11, wherein the protection layer comprises a lower removal by chemical-mechanical polishing rate than a removal rate of the lower electrode.

12. A method as claimed in claim 11, wherein the protection layer comprises a lower acoustic impedance than an acoustic impedance of the lower electrode.

13. A method as claimed in claim 9, wherein the protection layer comprises a seed layer for deposition of the piezoelectric layer.

14. A method as claimed in claim 13, wherein the seed layer comprises one of amorphous silicon dioxide and aluminum nitride.

15. A method as claimed in claim 9, wherein the protection layer comprises the same material as the piezoelectric layer.

16. A method as claimed in claim 9, wherein the insulating layer comprises a dielectric layer.

17. A method as claimed in claim 16, wherein the dielectric layer includes one of the group consisting of a silicon nitride layer, silicon oxide layer, silicon oxynitride.

18. The method as claimed in claim 17, wherein the piezoelectric layer is produced using one of the group consisting of AlN, ZnO and PZT.

19. The method as claimed in claim 9, wherein the lower electrode and the upper electrode include at least one of the group consisting of aluminum and tungsten.

20. The method as claimed in claim 9, wherein the resonator is a BAW resonator.

21. The method as claimed in claim 9, wherein the piezoelectric layer is produced using one of the group consisting of AlN, ZnO and PZT.
